(19) United States
(12) Patent Application Publication
(10) Pub. No.: US 2012/0114877 A1
(43) Pub. Date: May 10, 2012

(54) Radical Reactor with Multiple Plasma Chambers

(75) Inventor: Sang In LEE, Sunnyvale, CA (US)

(73) Assignee: SYNOS TECHNOLOGY, INC., Sunnyvale, CA (US)

(21) Appl. No.: 13/285,417

(22) Filed: Oct. 31, 2011

Related U.S. Application Data
(60) Provisional application No. 61/410,796, filed on Nov. 5, 2010.

(51) Int. Cl. C23C 16/452; H05H 1/24

(52) U.S. Cl. 427/569; 118/723 MP

(57) ABSTRACT

Two or more plasma chambers are provided in a radical reactor to generate radicals of gases under different conditions for use in atomic layer deposition (ALD) process. The radical reactor has a body with multiple channels and corresponding process chambers. Each plasma chamber is surrounded by an outer electrode and has an inner electrode extending through the chamber. When voltage is applied across the outer electrode and the inner electrode with gas present in the plasma chamber, radicals of the gas is generated in the plasma chamber. The radicals generated in the plasma chamber are then injected into a mixing chamber for mixing with radicals of another gas from another plasma chamber, and injected onto the substrate. By providing two or more plasma chambers, different radicals of gases can be generated within the same radical reactor, which obviates the need for separate radical generators.

### CROSS-REFERENCE TO RELATED APPLICATION

This application claims priority under 35 U.S.C. §119(e) to co-pending U.S. Provisional Patent Application No. 61/410,796, filed on Nov. 5, 2010, which is incorporated by reference herein in its entirety.

### BACKGROUND

1. Field of Art

The present invention relates to a radical reactor for depositing one or more layers of materials on a substrate using atomic layer deposition (ALD).

2. Description of the Related Art

An atomic layer deposition (ALD) is a thin film deposition technique for depositing one or more layers of material on a substrate. ALD uses two types of chemical, one is a source precursor and the other is a reactant precursor. Generally, ALD includes four stages: (i) injection of a source precursor, (ii) removal of a physical adsorption layer of the source precursor, (iii) injection of a reactant precursor, and (iv) removal of a physical adsorption layer of the reactant precursor. ALD can be a slow process that can take an extended amount of time or many repetitions before a layer of desired thickness can be obtained. Hence, to expedite the process, a vapor deposition reactor with a unit module (so-called a linear injector), as described in U.S. Patent Application Publication No. 2009/0165715 or other similar devices may be used to expedite ALD process. The unit module includes an injection unit and an exhaust unit for a source material (a source module), and an injection unit and an exhaust unit for a reactant (a reactant module).

A conventional ALD vapor deposition chamber has one or more sets of reactors for depositing ALD layers on substrates. As the substrate passes below the reactors, the substrate is exposed to the source precursor, a purge gas and the reactant precursor. The source precursor molecules deposited on the substrate reacts with reactant precursor molecules or the source precursor molecules are replaced with the reactant precursor molecules to deposit a layer of material on the substrate. After exposing the substrate to the source precursor or the reactant precursor, the substrate may be exposed to the purge gas to remove excess source precursor molecules or reactant precursor molecules from the substrate.

### SUMMARY

Embodiments relate to depositing one or more layers of material on a substrate using a radical reactor with a plurality of plasma chambers, each under different conditions for generating radicals of different gases. The radicals of gases may be formed in the plasma chambers under different conditions. Hence, the radical reactor is formed with a plurality of plasma chambers that are placed in appropriate conditions for generating the radicals of gases injected into the plasma chambers.

In one embodiment, the radical reactor has a body placed adjacent to a susceptor on which the substrate is mounted. The body may be formed with a first plasma chamber configured to receive a first gas, a second plasma chamber configured to receive a second gas, and a mixing chamber connected to the first plasma chamber and the second plasma chamber to receive radicals of the first gas and radicals of the second gas from the first plasma chamber and the second plasma chamber. The plasma chambers are located remotely from the substrate to prevent voltage applied to the plasma chambers from affecting the substrate or devices formed on the substrate.

In one embodiment, a first inner electrode extends within the first plasma chamber. The first inner electrode is configured to generate the radicals of the first gas within the first plasma chamber by applying a first voltage difference across the first inner electrode and a first outer electrode. A second inner electrode extends within the second plasma chamber. The second inner electrode is configured to generate the radicals of the second gas within the second plasma chamber by applying a second voltage difference across the second inner electrode and a second outer electrode. The first voltage difference is greater or smaller than the second voltage difference.

In one embodiment, the body is further formed with a mixing chamber in which the radicals of the first gas and the radicals or the second gas are mixed before coming into contact with the substrate.

In one embodiment, the body is further formed with a first channel connecting the first plasma chamber to a first gas source and a second channel connecting the second plasma chamber to a second gas source.

In one embodiment, the body is further formed with at least one first perforation connecting the first plasma chamber with the mixing chamber and at least one second perforation connecting the second plasma chamber with the mixing chamber.

In one embodiment, the first channel, the first electrode, the first plasma chamber, and the first perforation are aligned along a first plane. The second channel, the second electrode, the second plasma chamber, and the second perforation are also aligned along a second plane oriented with an angle with respect to the first plane.

In one embodiment, the first perforation and the second perforation are oriented toward a same interior area within the mixing chamber to facilitate mixing of the radicals.

In one embodiment, the radical reactor is placed above the susceptor to inject the radicals as the susceptor moves below the radical reactor.

In one embodiment, the body is formed with two outlets at opposite sides of the radical reactor.

In one embodiment, the body is formed with a first mixing chamber in which the radicals of the first gas and the radicals of the second gas are injected from the first plasma chamber and the second plasma chamber for mixing, a second mixing chamber facing the substrate for allowing mixed radicals to come in contact with the substrate, and a communication channel connecting the first mixing chamber and the second mixing chamber.

In one embodiment, the radical reactor is used for performing an atomic layer deposition (ALD) on the substrate.

Embodiments also relate to a deposition apparatus for depositing one or more layers of material on a substrate using atomic layer deposition (ALD). The deposition apparatus includes a radical reactor with a plurality of radical reactors formed therein to generate radicals of gases under different conditions.

Embodiments also relate to a method of depositing one or more layers on a substrate using atomic layer deposition (ALD). The method involves injecting a first gas into a first plasma chamber formed in a radical reactor. Radicals of the first gas are generated in the first plasma chamber under a first condition. A second gas is injected into a second plasma chamber formed in the radical reactor. Radicals of the second gas are generated in the second plasma chamber under a second condition different from the first condition. The radicals of the first gas and the radicals of the second gas are mixed in a mixing chamber formed in the radical reactor. The mixed radicals are injected onto the substrate.

In one embodiment, the first condition relates to applying a first level of voltage across an inner electrode and an outer electrode of the first plasma chamber and the second condition relates to applying a second level of voltage across an inner electrode and an outer electrode of the second plasma chamber.

### BRIEF DESCRIPTION OF DRAWINGS

FIG. 1 is a cross sectional diagram of a linear deposition device, according to one embodiment.

FIG. 2 is a perspective view of a linear deposition device, according to one embodiment.

FIG. 3 is a perspective view of a rotating deposition device, according to one embodiment.

FIG. 4 is a perspective view of reactors according to one embodiment.

FIG. 5A is a top view of a radical reactor according to one embodiment.

FIG. 5B is a cross sectional diagram of the radical reactor taken along line A-A′ of FIG. 5A, according to one embodiment.

FIG. 6 is a cross sectional diagram of the radical reactor taken along line B-B′ of FIG. 5A, according to one embodiment.

FIGS. 7 through 9 are cross section diagrams of radical reactors, according to various embodiments.

FIG. 10 is a flow chart illustrating a process of injecting mixed radicals onto a substrate, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to providing two or more plasma chambers in a radical reactor to generate radicals of gases under different conditions for use in atomic layer deposition (ALD) process. The radical reactor has a body with multiple channels and corresponding plasma chambers. Electrodes are placed in and around each plasma chamber to generate plasma when voltage is applied across the electrodes. The plasma generates radicals of gas present in the plasma chamber. The radicals generated in the plasma chamber are then injected into a mixing chamber for mixing with radicals of another gas from another plasma chamber, and then injected onto the substrate. By providing two or more plasma chambers in a radical reactor, the need for multiple radical reactors can be obviated.

A plasma chamber described herein refers to a cavity into which a gas is injected for generating radicals of the gas. Electrodes are placed in and/or around the plasma chamber to generate plasma in the plasma chamber as voltage is applied across the electrodes. The plasma chamber may be located remotely from a substrate to prevent plasma or electric sparks from affecting the substrate or devices on the substrate.

A mixing chamber described herein refers to a cavity in which radicals of two or more gases are mixed.

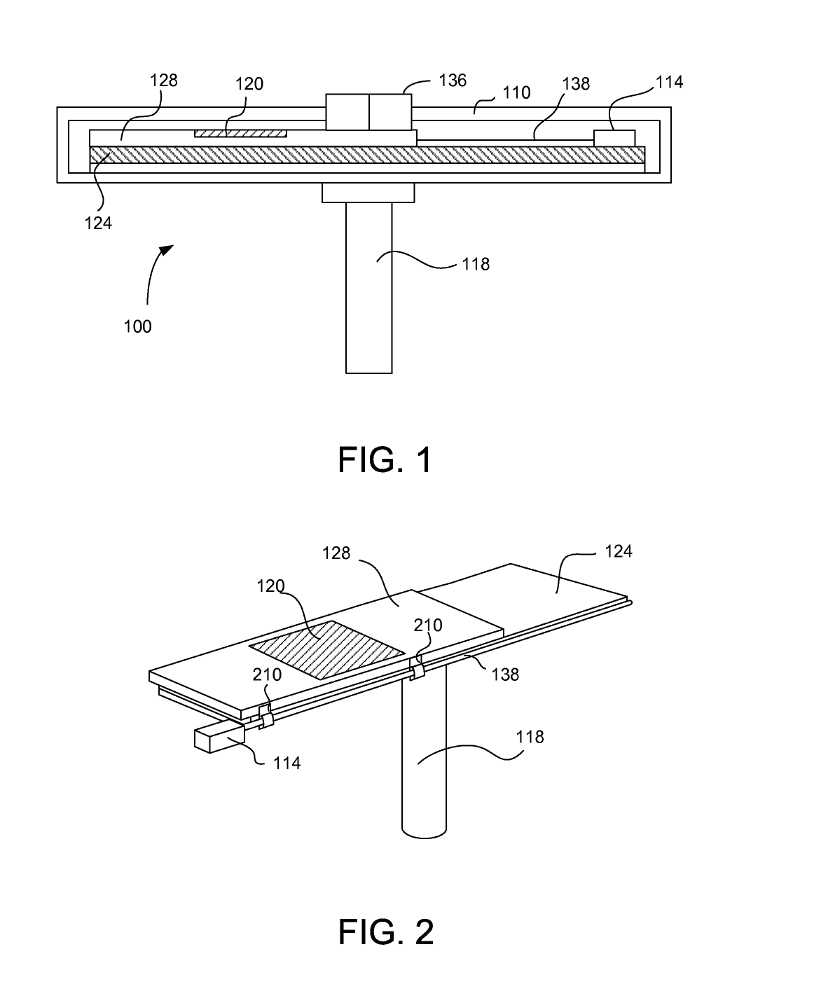

FIG. 1 is a cross sectional diagram of a linear deposition device 100 according to one embodiment. FIG. 2 is a perspective view of the linear position device 100 (without chamber walls 110 to facilitate explanation) of FIG. 1. The linear deposition device 100 may include, among other components, a support pillar 118, a process chamber 110 and one or more reactors 136. The reactors 136 may include one or more of injectors and radical reactors. Each of the injector modules injects source precursors, reactant precursors, purge gases or a combination of these materials onto the substrate 120. The radical reactors inject radicals of one or more gases onto the substrate 120. The radicals may function as source precursors, reactant precursors or material for treating the surface of the substrate 120.

The process chamber enclosed by the walls 110 may be maintained in a vacuum state to prevent contaminants from affecting the deposition process. The process chamber contains a susceptor 128 which receives a substrate 120. The susceptor 128 is placed on a support plate 124 for a sliding movement. The support plate 124 may include a temperature controller (e.g., a heater or a cooler) to control the temperature of the substrate 120. The linear deposition device 100 may also include lift pins (not shown) that facilitate loading of the substrate 120 onto the susceptor 128 or dismounting of the substrate 120 from the susceptor 128.

In one embodiment, the susceptor 128 is secured to brackets 210 that moves across an extended bar 138 with screws formed thereon. The brackets 210 have corresponding screws formed in their holes receiving the extended bar 138. The extended bar 138 is secured to a spindle of a motor 114, and hence, the extended bar 138 rotates as the spindle of the motor 114 rotates. The rotation of the extended bar 138 causes the brackets 210 (and therefore the susceptor 128) to make a linear movement on the support plate 124. By controlling the speed and rotation direction of the motor 114, the speed and direction of the linear movement of the susceptor 128 can be controlled. The use of a motor 114 and the extended bar 138 is merely an example of a mechanism for moving the susceptor 128. Various other ways of moving the susceptor 128 (e.g., use of gears and pinion at the bottom, top or side of the susceptor 128) may be used. Moreover, instead of moving the susceptor 128, the susceptor 128 may remain stationary and the reactors 136 may be moved.

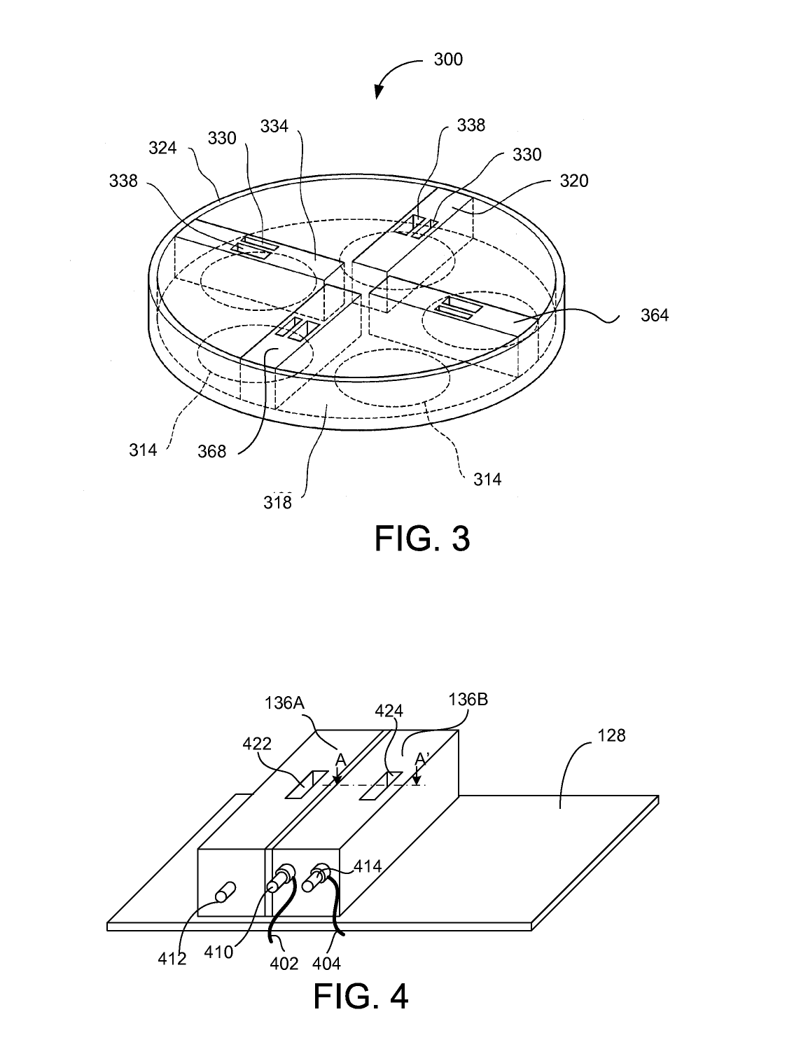

FIG. 3 is a perspective view of a rotating deposition device 300, according to one embodiment. Instead of using the linear deposition device 100 of FIG. 1, the rotating deposition device 300 may be used to perform the deposition process according to another embodiment. The rotating deposition device 300 may include, among other components, reactors 320, 334, 364, 368, a susceptor 318, and a container 324 enclosing these components. The susceptor 318 secures the substrates 314 in place. The reactors 320, 334, 364, 368 are placed above the substrates 314 and the susceptor 318. Either the susceptor 318 or the reactors 320, 334, 364, 368 rotate to subject the substrates 314 to different processes.

One or more of the reactors 320, 334, 364, 368 are connected to gas pipes via inlet 330 to receive source precursor, reactor precursor, purge gas and/or other materials. The materials provided by the gas pipes may be (i) injected onto the substrate 314 directly by the reactors 320, 334, 364, 368, (ii) after mixing in a chamber inside the reactors 320, 334, 364, 368, or (iii) after conversion into radicals by plasma generated within the reactors 320, 334, 364, 368. After the materials are injected onto the substrate 314, the redundant materials may be exhausted through outlets 330.

Embodiments of radical reactors described herein can be used in deposition devices such as the linear deposition device 100, the rotating deposition device 300 or other types of deposition devices. FIG. 4 is an example of a radical reactor 136B placed in tandem with an injector 136A in the linear deposition device 100. The susceptor 128 mounted with the substrate 120 reciprocates in two directions (i.e., right and left directions in FIG. 4) to expose the substrate 120 to gases and/or radicals injected by the injector 136A and the radical reactor 136B. Although only one injector 136A and one radical reactor 136B are illustrated in FIG. 4, many more injectors and/or radical reactors may be provided in the linear deposition device 100. It is also possible to provide only the radical reactor 136B without the injector 136A.

The injector 136A receives gas through a pipe 412 and injects the gas onto the substrate 120 as the susceptor 128 moves below the injector 136A. The injected gas may be a source gas, a reactant gas, purge gas or a combination thereof. After being injected onto the substrate 120, excess gas in the injector 136A is discharged via an outlet 422. The outlet 422 is connected to a pipe (not shown) to discharge the excess gas outside the linear deposition device 100.

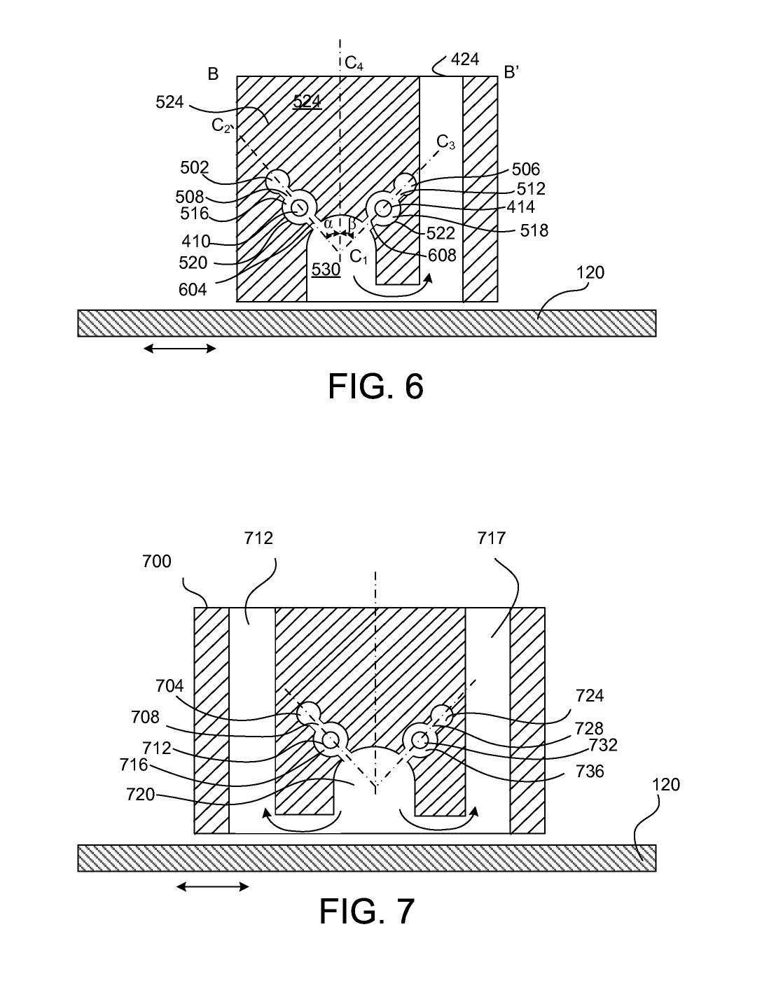

The radical reactor 136B receives gases via pipes (not shown) and has two plasma chambers. Channels are formed in the body of the radical reactor 136B to convey the received gases to the plasma chambers. Two inner electrodes 410, 414 extend longitudinally across the radical reactor 137B and are connected to a voltage source (not shown) or ground (not shown) via wires 402, 404. The inner electrodes 410, 414 are placed inside plasma chambers, as described below in detail with reference to FIG. 6. The outer electrodes in the radical reactor 136B are connected to ground or a voltage source. In one embodiment, the conductive body of the radical reactor 136B functions as the outer electrodes. An outlet 424 is formed in the body of the radical reactor 136B to discharge excess radicals and/or gases reverted to an inactive state from the radicals after being injected onto the substrate 120. The outlet 424 is connected to a pipe (not shown) to discharge the excess radicals and/or gases outside the linear deposition device 100.

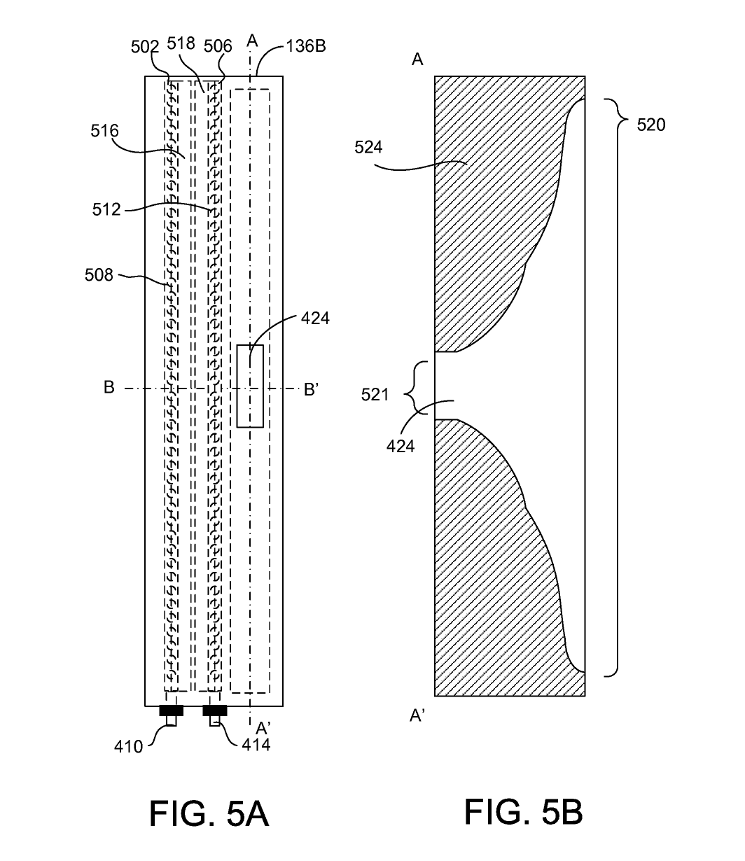

FIG. 5A is a top view of the radical reactor 136B according to one embodiment. The inner electrodes 410, 414 extend longitudinally along a cylindrical plasma chamber 516, 518, respectively (illustrated more clearly in FIG. 6). The plasma chambers 516, 518 are connected to channels 502, 506 via holes 508, 512 to receive gases injected into the radical reactor 136B. Instead of holes 508, 512, slits or other perforations may be formed to convey the gases to the plasma chambers 516, 518. The channels 502, 506 are connected to different gas sources providing different gases so that the plasma chambers 516, 518 are filled with different gases.

FIG. 5B is a cross sectional diagram of the radical reactor 136B taken along line A-A′ of FIG. 5A, according to one embodiment. The radical reactor 136B has a body 524 in which an outlet 424 is formed. The outlet 424 is shaped so that its bottom portion 520 extends longitudinally across the radical reactor 136B whereas the upper portion 521 has a narrower width for connection to a pipe (not shown). By extending the bottom portion 520 across the radical reactor 136B, the outlet 424 can discharge excess radicals/gas more effectively.

FIG. 6 is a cross sectional diagram of the radical reactor 136B taken along line B-B′ of FIG. 5A, according to one embodiment. In the body 524 of the radical reactor 136B, two plasma chambers 516, 518 are formed at the right and left sides of the mixing chamber 530. Each of the two plasma chambers 516, 518 is connected to channels 502, 506 via holes 508, 512 to receive gases and to the mixing chamber 530 via slits 604 and 608. The inner electrodes 410, 414 extend longitudinally along the radical reactor 137B. In the embodiment of FIG. 6, the channel 502, the holes 508, the plasma chamber 516 and the slit 604 are aligned along plane C₁-C₂. Plane C₁-C₂ is slanted at an angle of α with respect to a vertical plane C₁-C₄. The channel 506, the holes 512, the plasma chamber 518 and the slit 608 are aligned along plane C₁-C₃. Plane C₁-C₃ is slanted at an angle of β with respect to the vertical plane C₁-C₄ opposite to the channel 502, the holes 508, the plasma chamber 516 and the slit 604. The angle α and the angle β may be of identical or different amplitude.

In other embodiments, one or more of the channels, the holes, plasma chambers and slits are not aligned along the same plane but placed in different arrangements. For example, a channel may be provided at a horizontally left or right side of the channel or vertically above the channel. Various other arrangements of channels, holes, plasma chambers and slits can also be used.

In the embodiment of FIG. 6, a first gas is injected into the plasma chamber 516 via the channel 502 and holes 508. By applying voltage across the inner electrode 410 and the outer electrode 520, plasma is generated in the plasma chamber 516, producing radicals of the first gas within the plasma chamber 516. The generated radicals of the first gas are then injected into the mixing chamber 530 via the slit 604. Also, a second gas is injected into the plasma chamber 518 via the channel 506 and holes 512. By applying voltage across the inner electrode 414 and the outer electrode 522, plasma is generated within the plasma chamber 518, producing radicals of the second gas within the plasma chamber 518. The generated radicals of the second gas are then injected into the mixing chamber 530 via the slit 608.

The slits 604 and 608 are oriented toward an area of the mixing chamber 530 (around point C₁ of the mixing chamber 530 in FIG. 6) to inject the radicals into the same area in the mixing chamber 530. In this way, the mixing of radicals injected from the slits 604, 608 can be faciliated. That is, the slits 604, 608 are configured to inject the radicals of the gases at angles of α and β with respect to the vertical plane C₁-C₄. In this way, radicals of both gases are effectively mixed within the mixing chamber 530 before the radicals come into contact with the substrate 120. The dimension of the mixing chamber 530 may be configured to allow sufficient diffusion of the radicals within the mixing chamber 530 before coming into contact with the substrate 120. Some of the radicals may revert to an inactive state before, during or after coming into contact with the substrate 120. The remaining radicals and reverted gases are discharged through the outlet 424.

As seen in Table 1 below, different types of gases have different levels of ionization energy. Hence, different levels of voltage are applied between the inner electrode and the outer electrode of the plasma chamber depending on the types of gas supplied to the plasma chamber. To generate radicals of different gases, a corresponding number of plasma chambers and sets of electrodes may be needed due to different levels of ionization energy for different gases.

TABLE 1

| Gas | Ionization energy (eV) |
|---|---|
| H₂ | 15.4 |
| N₂ | 15.58 |
| O₂ | 12.06 |
| CO | 14.0 |
| CO₂ | 13.77 |
| CH₄ | 12.6 |
| C₂H₆ | 11.5 |
| C₃H₈ | 11.1 |
| NH₃ | 11.2 |
| NO | 9.25 |
| N₂O | 12.9 |
| H₂O | 18.3 |
| He | 24.48 |
| Ne | 21.56 |
| Ar | 15.78 |
| Kr | 14.00 |
| Xe | 12.13 |

In the embodiment of FIG. 6, two separate plasma chambers 516, 518 are provided to receive two different gases. The electrodes 410, 520 associated with the plasma chamber 516 can be applied with a voltage difference that is lower or higher than another voltage difference between the electrodes 414, 522 associated with the plasma chamber 518. By providing two different plasma chambers 516, 518, radicals of two different gases with different ionization energy can be generated in a single radical reactor 138B. Other conditions (e.g., pressure and temperature) of the gases in both plasma chambers 516, 518 may be differed to generate the radicals as desired.

In summary, the radical reactor 136B functions as two radical reactors with one plasma chamber. By incorporating two radical reactors into one radical reactor, the space and cost of the linear deposition device 100 can be reduced.

FIG. 7 is a cross sectional diagram of a radical reactor 700 according to another embodiment. The radical reactor 700 of FIG. 7 has two outlets 712, 717 formed at opposite sides of the radical reactor 700. The radical reactor 700 has channels 704, 724 that provide gases to plasma chambers 716, 736 via channels 704, 724 and holes 708, 728. Inner electrodes 712, 732 extend along the longitudinal direction of the plasma chambers 716, 736 to generate radicals in the plasma chambers 716, 736 in conjunction with outer electrodes surrounding the plasma chambers 716, 736. By providing outlets 712, 717 at both sides, the excess gases or radicals of the gases can be discharged more effectively from the radical reactor 700.

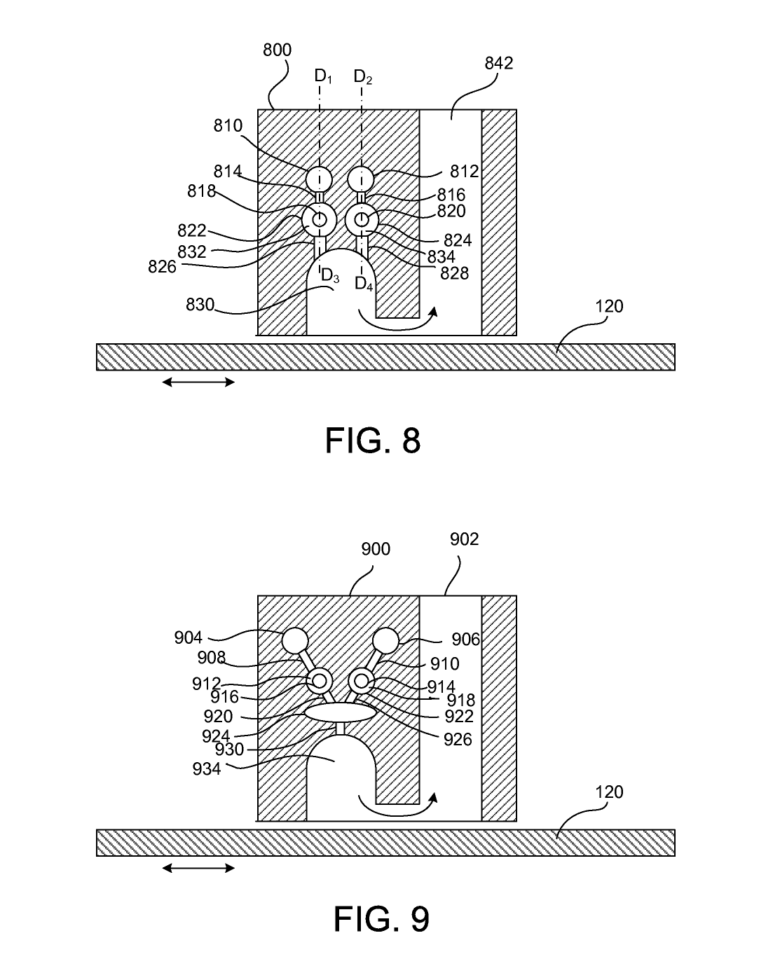

FIG. 8 is a cross sectional diagram of a radical reactor 800 according to another embodiment. The radical reactor 800 has a structure similar to the radical reactor 136B except that the channels 810, 812, holes 814, 816, plasma chambers 832, 834, inner electrodes 818, 820 and slits 826, 828 are aligned along vertical planes D₁-D₃ and D₂-D₄. Specifically, the channel 810 receives a first gas from a gas source and injects the first gas into the plasma chamber 832 via holes 814. The channel 812 receives a second gas from another gas source and injects the second gas into the plasma chamber 834 via holes 816.

The radicals of the first and second gases are generated in the plasma chambers 832, 834 by applying voltage across the inner electrodes 818, 820 and outer electrodes 822, 824. The generated radicals are then are injected into a mixing chamber 830 via slits 826, 828. The mixing chamber 830 may have sufficient height to allow adequate mixing of the radicals as the radicals travel down the mixing chamber 830 onto the substrate 120. The remaining radicals and/or gases are discharged via an outlet 842.

FIG. 9 is a cross sectional diagram of a radical reactor 900 according to one embodiment. The radical reactor 900 has a similar configuration of channels 904, 906, holes 908, 910, plasma chambers 912, 918, inner electrodes 916, 914 and slits 920, 926 as those of the radical reactor 136B. However, the radical reactor 900 is different from the radical reactor 136B in that the radical reactor 900 includes a separate first mixing chamber 924 where the radicals are mixed. The mixed radicals are then injected into a second mixing chamber 934 via a communication channel 930. The mixed radicals come into contact with the substrate 120 below the second mixing chamber 934. By providing a separate mixing chamber 924 remote from the substrate 120, the radicals are mixed more uniformly before coming into contact with the substrate 120. The remaining radicals and/or gases (reverted to an inactive state) are discharged via an outlet 902 provided at one side of the radical reactor 900. In another embodiment, the outlets are formed on both sides of the radical reactor 900.

The radical reactors of various other configurations may also be used. Although embodiments of radical reactors in FIGS. 4 through 9 include two plasma chambers, other embodiments may include more than two plasma chambers. Also, the plasma chambers and electrodes may have shapes other than cylindrical shapes. It is also possible to have different chambers located at different vertical locations of the radical reactor. Further, communication channels other than slits or holes may be connected to the plasma chambers.

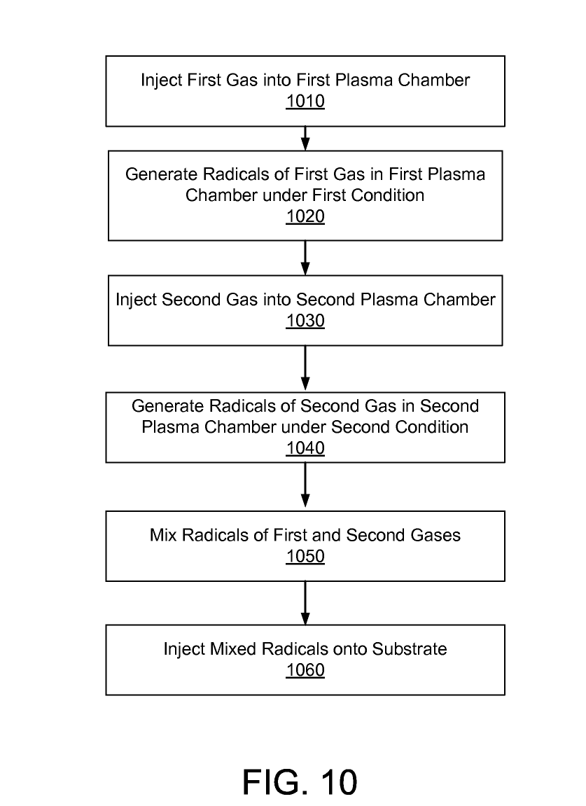

FIG. 10 is a flow chart illustrating a process of injecting mixed radicals onto a substrate, according to one embodiment. A first gas is injected 1010 into a first plasma chamber in a radical reactor via a channel connected to a gas source. Within the first plasma chamber, radicals of the first gas are generated 1020 under a first condition. The first condition may include applying a first level of voltage difference across an inner electrode and an outer electrode associated with the first plasma chamber. The first condition may include maintaining the pressure and temperature of plasma or gas within the first plasma chamber within certain ranges.

A second gas is injected 1030 into a second plasma chamber of the same radical reactor via another channel connected to a gas source. Within the second plasma chamber, radicals of the first gas are generated 1040 under a second condition. The second condition may include applying a second level of voltage difference across an inner electrode and an outer electrode associated with the second plasma chamber. The second condition may include maintaining the pressure and temperature of plasma or gas within the second plasma chamber within certain ranges At least one element of the second condition is different from the counterpart element of the first condition.

The radicals generated in the first and second plasma chambers are then injected into a mixing chamber where the radicals are mixed 1050. The mixed radicals are then injected 1060 onto the substrate.

The sequence of processes in FIG. 10 is merely illustrative, and different sequence may be used. For example, the processes of injecting 1010 the first gas and generating 1020 radicals of the first gas can be performed in parallel or after the processes of injecting 1030 the second gas and generating 1040 radicals of the second gas.

Although the present invention has been described above with respect to several embodiments, various modifications can be made within the scope of the present invention. Accordingly, the disclosure of the present invention is intended to be illustrative, but not limiting, of the scope of the invention, which is set forth in the following claims.

What is claimed is:

1. A radical reactor for depositing one or more layers of material on a substrate, comprising:
a body placed adjacent to a susceptor on which the substrate is mounted, the body formed with:
a first plasma chamber configured to receive a first gas,
a second plasma chamber configured to receive a second gas, and
a mixing chamber connected to the first plasma chamber and the second plasma chamber to receive radicals of the first gas and radicals of the second gas from the first plasma chamber and the second plasma chamber;
a first inner electrode extending within the first plasma chamber, the first inner electrode configured to generate the radicals of the first gas within the first plasma chamber by applying a first voltage difference across the first inner electrode and a first outer electrode; and
a second inner electrode extending within the second plasma chamber, the second inner electrode configured to generate the radicals of the second gas within the second plasma chamber by applying a second voltage difference across the second inner electrode and a second outer electrode.

2. The radical reactor of claim 1, wherein the body is further formed with a mixing chamber in which the radicals of the first gas and the radicals of the second gas are mixed before coming into contact with the substrate.

3. The radical reactor of claim 2, wherein the body is further formed with a first channel connecting the first plasma chamber to a first gas source and a second channel connecting the second plasma chamber to a second gas source.

4. The radical reactor of claim 3, wherein the body is further formed with at least one first perforation connecting the first plasma chamber with the mixing chamber, and at least one second perforation connecting the second plasma chamber with the mixing chamber.

5. The radical reactor of claim 4, wherein the first channel, the first inner electrode, the first plasma chamber, and the first perforation are aligned along a first plane; and the second channel, the second inner electrode, the second plasma chamber, and the second perforation are aligned along a second plane oriented with an angle with respect to the first plane.

6. The radical reactor of claim 4, wherein the first perforation and the second perforation are oriented toward a same interior area within the mixing chamber.

7. The radical reactor of claim 1, wherein the radical reactor is placed above the susceptor.

8. The radical reactor of claim 1, wherein the body is formed with two outlets at opposite sides of the radical reactor.

9. The radical reactor of claim 1, wherein the body is formed with a first mixing chamber in which the radicals of the first gas and the radicals of the second gas are injected from the first plasma chamber and the second plasma chamber for mixing, a second mixing chamber facing the substrate for allowing mixed radicals to come in contact with the substrate, and a communication channel connecting the first mixing chamber and the second mixing chamber.

10. The radical reactor of claim 1, wherein the radical reactor is used for performing an atomic layer deposition (ALD) on the substrate.

11. A deposition apparatus for depositing one or more layers of material on a substrate using atomic layer deposition (ALD), comprising:
a susceptor configured to mount a substrate;
a radical reactor comprising:
a body placed adjacent to the susceptor, the body formed with:
a first plasma chamber configured to receive a first gas,
a second plasma chamber configured to receive a second gas, and
a mixing chamber connected to the first plasma chamber and the second plasma chamber to receive radicals of the first gas and radicals of the second gas from the first plasma chamber and the second plasma chamber;
a first inner electrode extending within the first plasma chamber, the first inner electrode configured to generate the radicals of the first gas within the first plasma chamber by applying a first voltage difference across the first inner electrode and a first outer electrode; and
a second inner electrode extending within the second plasma chamber, the second inner electrode configured to generate the radicals of the second gas within the second plasma chamber by applying a second voltage difference across the second inner electrode and a second outer electrode; and
an actuator configured to cause relative movement between the susceptor and the radical reactor.

12. The deposition apparatus of claim 11, wherein the body is further formed with a mixing chamber in which the radicals of the first gas and the radicals of the second gas are mixed before coming into contact with the substrate.

13. The deposition apparatus of claim 12, wherein the body is further formed with a first channel connecting the first plasma chamber to a first gas source and a second channel connecting the second plasma chamber to a second gas source.

14. The deposition apparatus of claim 13, wherein the body is further formed with at least one first perforation connecting the first plasma chamber with the mixing chamber and at least one second perforation connecting the second plasma chamber with the mixing chamber.

15. The deposition apparatus of claim 14, wherein the first channel, the first inner electrode, the first plasma chamber, and the first perforation are aligned along a first plane; and the second channel, the second inner electrode, the second plasma chamber, and the second perforation are aligned along a second plane oriented with an angle with respect to the first plane.

16. The deposition apparatus of claim 14, wherein the first perforation and the second perforation are oriented toward a same interior area within the mixing chamber.

17. The deposition apparatus of claim 11, wherein the body is formed with two outlets at opposite sides of the radical reactor.

18. The deposition apparatus of claim 11, wherein the body is formed with a first mixing chamber in which the radicals of the first gas and the radicals of the second gas are injected from the first plasma chamber and the second plasma chamber for mixing, a second mixing chamber facing the substrate for allowing mixed radicals to come in contact with the substrate, and a communication channel connecting the first mixing chamber and the second mixing chamber.

19. A method of depositing one or more layers on a substrate using atomic layer deposition (ALD), comprising:
injecting a first gas into a first plasma chamber formed in a radical reactor;
generating radicals of the first gas in the first plasma chamber under a first condition;
injecting a second gas into a second plasma chamber formed in the radical reactor;
generating radicals of the second gas in the second plasma chamber under a second condition different from the first condition;
mixing the radicals of the first gas and the radicals of the second gas in a mixing chamber formed in the radical reactor; and
injecting the mixed radicals onto the substrate.

20. The method of claim 19, wherein the first condition comprises applying a first level of voltage across an inner electrode and an outer electrode of the first plasma chamber and the second condition comprises applying a second level of voltage across an inner electrode and an outer electrode of the second plasma chamber.
